(19) United States
(12) Patent Application Publication
(10) Pub. No.: US 2026/0198188 A1
(43) Pub. Date: Jul. 9, 2026

(54) DISPLAY DEVICE, METHOD OF FABRICATING THE DISPLAY DEVICE, AND ELECTRONIC DEVICE

(71) Applicant: Samsung Display Co., Ltd., Yongin-si (KR)

(72) Inventor: JUNHONG PARK, Yongin-si (KR)

(21) Appl. No.: 19/288,316

(22) Filed: Aug. 1, 2025

(30) Foreign Application Priority Data
Jan. 7, 2025 (KR) 10-2025-0002342

(51) Int. Cl. H10K 59/124; H10K 59/12

(52) U.S. Cl. CPC H10K 59/124; H10K 59/1201

(57) ABSTRACT

Provided is a display device including a substrate, a thin-film transistor on the substrate, an inorganic film layer on the thin-film transistor, and a light-emitting element electrically connected to the thin-film transistor and disposed on the inorganic film layer. The light-emitting element includes a pixel electrode, a common electrode positioned on the pixel electrode, and an emission layer disposed between the pixel electrode and the common electrode, the inorganic film layer includes a plurality of concave portions, a filling material is disposed in each of the plurality of concave portions, a top surface of the filling material includes a concave first groove, and a top surface of the pixel electrode includes a second groove, wherein a portion of a bottom surface of the pixel electrode corresponds to the second groove and is flush with the top surface of the filling material.

This application claims priority to Korean Patent Application No. 10-2025-0002342, filed on January 7, 2025, and all the benefits accruing therefrom under 35 U.S.C. §119, the content of which in its entirety is herein incorporated by reference.

### BACKGROUND

### 1. Field

Embodiments relate to a display device, a method of fabricating the display device, and an electronic device.

### 3. Description of the Related Art

Along with the development of various electronic devices such as, for example, mobile phones, PDAs, computers, and large-screen TVs, various types of display devices which may be used with such electronic devices have been developed. For example, display devices widely used in the market include liquid crystal display devices, each of which has a backlight unit, or organic light-emitting display devices, each of which emits different colors of light from respective pixels.

The above information described in the description of the related art is intended to enhance understanding of the background of the disclosure and may therefore include information which does not constitute the prior art.

### SUMMARY

Embodiments of the disclosure may provide a display device in which concave shapes are arranged in light-emitting areas of light-emitting elements to improve display quality, a method of fabricating the display device, and an electronic device.

However, the technical problems to be solved by the disclosure are not limited to those described herein, and other problems not mentioned will be apparent to a person of ordinary knowledge in the art from the following description of the disclosure.

According to embodiments of the disclosure, a display device includes: a substrate; a thin-film transistor on the substrate; an inorganic film layer on the thin-film transistor; and a light-emitting element electrically connected to the thin-film transistor and disposed on the inorganic film layer, wherein the light-emitting element includes a pixel electrode, a common electrode positioned on the pixel electrode, and an emission layer disposed between the pixel electrode and the common electrode, the inorganic film layer includes a plurality of concave portions, a filling material is disposed in each of the plurality of concave portions, a top surface of the filling material includes a concave first groove, and a top surface of the pixel electrode includes a second groove, wherein a portion of a bottom surface of the pixel electrode corresponds to the second groove and is flush with the top surface of the filling material.

In an embodiment, a bottom surface of the emission layer may be flush with the top surface of the pixel electrode, and a bottom surface of the common electrode may be flush with the top surface of the emission layer.

In an embodiment, a depth of the second groove may be 0.18 μm or less.

In an embodiment, a width of the second groove may range from 0.9 μm to 1.1 μm.

In an embodiment, a thickness of the inorganic film layer may range from 0.8 μm to 1.8 μm.

In an embodiment, the display device may further include an organic film layer between the thin-film transistor and the inorganic film layer.

In an embodiment, the filling material may include an organic material.

In an embodiment, the display device may further include a pixel defining film covering peripheral portions of the pixel electrode and having a first opening defining a light-emitting area of the light-emitting element.

In an embodiment, the second groove may be provided as a plurality of second grooves, and the plurality of second grooves may be provided on the top surface of the pixel electrode and overlap the light-emitting area.

In an embodiment, the display device may further include a color filter which is disposed corresponding to the first opening.

In an embodiment, the display device may further include a black matrix positioned on the pixel defining film and having a second opening corresponding to the first opening.

According to other embodiments of the disclosure, a method of fabricating a display device includes: preparing a substrate and a thin-film transistor on the substrate; forming an inorganic film layer including a plurality of concave portions on the thin-film transistor; forming a filling material in each of the plurality of concave portions; and forming a light-emitting element which is electrically connected to the thin-film transistor and disposed on the inorganic film layer, wherein the light-emitting element includes a pixel electrode, a common electrode positioned on the pixel electrode, and an emission layer disposed between the pixel electrode and the common electrode, a top surface of the filling material includes a concave first groove, and a top surface of the pixel electrode includes a second groove, wherein a portion of a bottom surface of the pixel electrode corresponds to the second groove and is flush with the top surface of the filling material.

In an embodiment, the forming of the inorganic film layer may include: forming a photoresist layer by coating the inorganic film layer with a photoresist material; forming a photoresist pattern on the photoresist layer; and patterning the concave portions using the photoresist pattern as a mask.

In an embodiment, forming the filling material in each of the concave portions may be between the forming of the inorganic film layer and the forming of the light-emitting element.

In an embodiment, the forming of the light-emitting element may include: placing the pixel electrode on the inorganic film layer and the filling material; placing the emission layer on the pixel electrode; forming a pixel defining film covering peripheral portions of the pixel electrode and having a first opening defining a light-emitting area of the light-emitting element; and placing the common electrode on the emission layer, wherein the second groove is provided as a plurality of second grooves provided on the top surface of the pixel electrode and overlapping the light-emitting area.

In an embodiment, a bottom surface of the emission layer may be flush with the top surface of the pixel electrode, and a bottom surface of the common electrode may be flush with the top surface of the emission layer.

In an embodiment, a width of the second groove may range from 0.9 μm to 1.1 μm.

According to other embodiments of the disclosure, an electronic device includes a display device, wherein the display device includes: a substrate; a thin-film transistor on the substrate; an inorganic film layer on the thin-film transistor; and a light-emitting element electrically connected to the thin-film transistor and disposed on the inorganic film layer, wherein the light-emitting element includes a pixel electrode, a common electrode positioned on the pixel electrode, and an emission layer disposed between the pixel electrode and the common electrode, the inorganic film layer includes a plurality of concave portions, a filling material is disposed in each of the plurality of concave portions, a top surface of the filling material includes a concave first groove, and a top surface of the pixel electrode includes a second groove, wherein a portion of a bottom surface of the pixel electrode corresponds to the second groove and is flush with the top surface of the filling material.

In an embodiment, the electronic device may further include an antireflective layer disposed on the light-emitting element, wherein the antireflective layer includes a color filter which filters light generated by the light-emitting element and a black matrix surrounding the color filter.

In an embodiment, the electronic device may be absent a polarizer.

### BRIEF DESCRIPTION OF THE DRAWINGS

The accompanying drawings illustrate example embodiments of the disclosure and, together with the following detailed description, serve to provide further understanding of the technical spirit of the disclosure, and the disclosure is therefore not to be construed as being limited to the drawings.

FIG. 1 is a plan view schematically illustrating portions of a display device according to embodiments of the disclosure;

FIG. 2 is a cross-sectional view schematically illustrating an example of part I of the display device illustrated in FIG. 1;

FIG. 3 is an equivalent circuit diagram schematically illustrating a pixel circuit usable in the display device;

FIG. 4 is an enlarged view of area A of an example of the display device illustrated in FIG. 2;

FIGS. 5A, 5B, and 5C illustrate images of reflection diffraction patterns of display devices according to comparative examples and an experimental example;

FIG. 6 is an enlarged view of area A of another example of the display device illustrated in FIG. 2;

FIGS. 7 to 15 are cross-sectional views illustrating a fabrication process of a display device according to embodiments of the disclosure;

FIG. 16 is a block diagram illustrating an electronic device according to embodiments of the disclosure; and

FIG. 17 schematically illustrates electronic devices according to various embodiments.

### DETAILED DESCRIPTION

The disclosure may have various modifications and various embodiments, and thus specific embodiments will be illustrated in the drawings and described in detail in the detailed description. The effects and features of the disclosure and how to accomplish the same will be apparent with reference to the following detailed description together with the drawings. However, the disclosure is not limited to the embodiments disclosed below, but may be implemented in various forms.

In the following embodiments, terms, such as first and second, as used herein do not have a limited meaning but are used for the purpose of distinguishing one component from another.

In the following embodiments, singular forms include plural referents unless the context clearly indicates otherwise.

In the following embodiments, terms, such as “comprise/include” or “have”, are intended to imply the presence of a feature or a component described in the specification and do not preclude the possibility that one or more other features or components may be added.

In the following embodiments, when a portion, such as a unit, a region, or a component, is referred to as being above or on another portion, the portion may be directly above or on the other portion or an intervening portion, such as a unit, a region, or a component, may also be present between the two portions.

In the following embodiments, terms, such as “connect” or “couple”, do not necessarily mean a direct and/or fixed connection or coupling of two members, unless the context clearly indicates otherwise, and do not exclude the presence of other members provided between the two members.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially flat” means approximately or actually flat.

In the drawings, components may be exaggerated or reduced in size for ease of explanation. For example, the sizes and thicknesses of the respective components illustrated in the drawings are arbitrary for ease of explanation, and therefore the following embodiments are not necessarily limited thereto.

Hereinafter, example embodiments of the disclosure will be described in detail with reference to the accompanying drawings, in which identical or corresponding components are designated by the same reference numerals and repeated descriptions thereof are omitted.

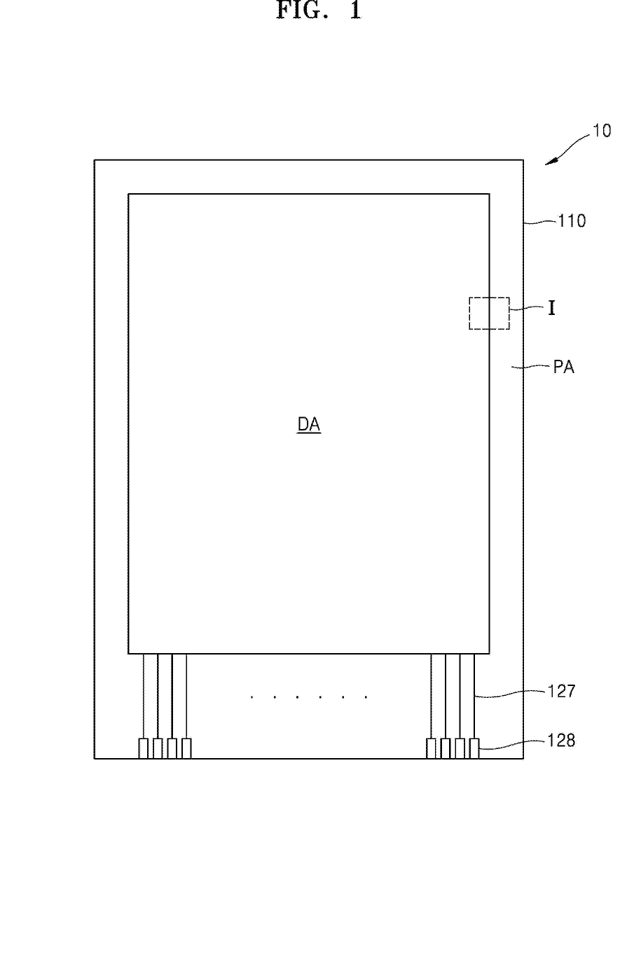

FIG. 1 is a plan view schematically illustrating portions of a display device according to embodiments of the disclosure.

Referring to FIG. 1, a display device 10 includes a display area DA which displays an image on a substrate 110 and a peripheral area PA which is a non-display area positioned outside the display area DA and does not display an image.

The display area DA may have a rectangular shape. The peripheral area PA may surround the display area DA. However, these are not intended to be limiting, and the shape of the display area DA and the shape of the peripheral area PA may be designed relative to each other.

The display area DA includes a plurality of light-emitting elements PX, and wiring 127 including scan lines electrically connected to the plurality of light-emitting elements PX, signal lines such as, for example, data lines, and power lines such as, for example, driving voltage lines is electrically connected to pad electrodes 128.

In an embodiment of the disclosure, the display device 10 is illustrated as having a planar display surface, but is not limited thereto. The display device 10 may also include a curved display surface or a three-dimensional display surface. The three-dimensional display surface may include a plurality of display areas facing in different directions, for example, multi-angled columnar display surfaces.

The display device 10 according to the disclosure may be a rigid display device. However, this is not intended to be limiting, and the display device 10 according to the disclosure may be a flexible display device. In the present embodiment, the display device 10 useable in a portable terminal is illustrated as an example. Although not illustrated, electronic modules, a camera module, a power module, and the like mounted on a motherboard may be accommodated in a housing and form a portable terminal. The display device 10 according to the disclosure may be used in large electronic devices such as, for example, televisions and monitors, as well as small and medium-sized electronic devices such as, for example, tablets, vehicle navigation systems, game consoles, and smart watches.

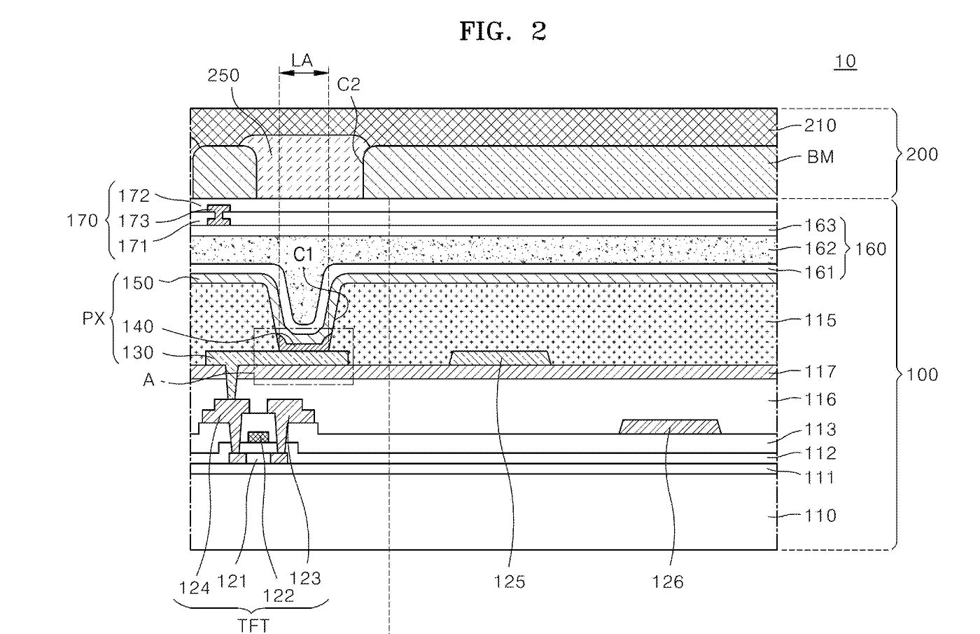

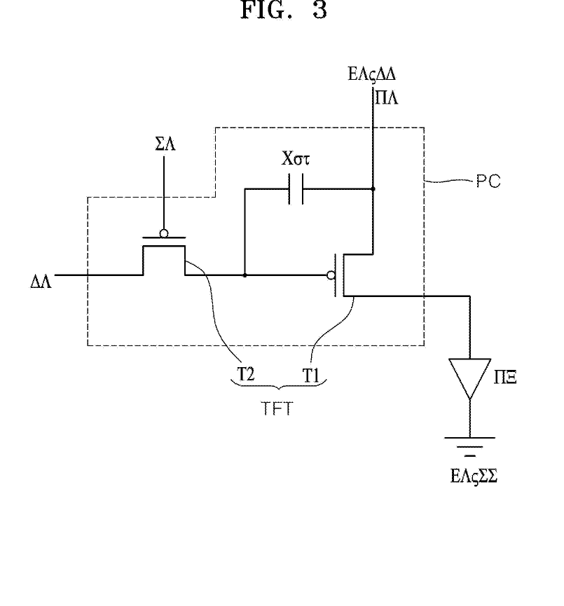

FIG. 2 is a cross-sectional view schematically illustrating an example of part I of the display device illustrated in FIG. 1, and FIG. 3 is an equivalent circuit diagram schematically illustrating a pixel circuit usable in the display device.

Referring to FIG. 2, the display device 10 may include a display layer 100 and an antireflective layer 200 on the display layer 100. The display layer 100 may include a substrate 110, a thin-film transistor TFT on the substrate 110, an inorganic film layer 117 on the thin-film transistor TFT, and a light-emitting element PX electrically connected to the thin-film transistor TFT on the inorganic film layer 117.

The display layer 100 may further include a thin-film encapsulation layer 160 on the light-emitting element PX and a touch sensing layer 170 on the thin-film encapsulation layer 160.

The antireflective layer 200 may include a color filter 250 on the touch sensing layer 170 and a black matrix BM positioned in the same plane as the color filter 250.

Although not illustrated, the display device 10 may further include other components disposed on the antireflective layer 200. For example, a window substrate, a cover member, or the like may be further disposed on the antireflective layer 200.

The substrate 110 may be formed of a variety of materials, such as, for example, glass, metal, or plastic. For example, the substrate 110 may be a flexible substrate including a polymeric resin such as, for example, polyether sulfone, polyacrylate, polyetherimide, polyethylene naphthalate, polyethylene terephthalate, polyphenylene sulfide, polyarylate, polyimide, polycarbonate, or cellulose acetate propionate.

A plurality of thin-film transistors TFT may be disposed on the substrate 110. The display area DA is an area for displaying an image, and the plurality of thin-film transistors TFT and a plurality of light-emitting elements PX electrically connected to the respective thin-film transistors TFT may be disposed on the substrate 110.

A buffer layer 111 including an inorganic material, such as, for example, silicon oxide, silicon nitride, and/or silicon oxynitride, may be provided between the thin-film transistor TFT and the substrate 110. The buffer layer 111 may serve to increase the smoothness of the surface of the substrate 110 or to prevent or reduce the entrance of impurities into the semiconductor layer 121 through the substrate 110.

The thin-film transistor TFT may include a semiconductor layer 121, a gate electrode 122, a source electrode 123, and a drain electrode 124.

The semiconductor layer 121 may include amorphous silicon, polycrystalline silicon, or an organic semiconductor material.

A gate electrode 122 may be disposed over the semiconductor layer 121. In response to a signal applied to the gate electrode 122, the source electrode 123 and the drain electrode 124 may electrically communicate with each other. The gate electrode 122 may be formed as a single or multiple layers of one or more materials of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu), taking into account adhesion to adjacent layers, surface flatness of the layers stacked, and processability.

To ensure insulation between the semiconductor layer 121 and the gate electrode 122, a gate insulating film 112 including an inorganic material, such as, for example, silicon oxide, silicon nitride, and/or silicon oxynitride, may be provided between the semiconductor layer 121 and the gate electrode 122.

An interlayer insulating film 113 including an inorganic material, such as, for example, silicon oxide, silicon nitride, and/or silicon oxynitride, may be disposed over the gate electrode 122.

A source electrode 123 and a drain electrode 124 are disposed on the interlayer insulating film 113. The source electrode 123 and the drain electrode 124 may be electrically connected to the semiconductor layer 121 through contact holes formed in the interlayer insulating film 113 and the gate insulating film 112.

The source electrode 123 and the drain electrode 124 may be formed as a single or multiple layers of one or more materials of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu).

Various structures and wiring may be disposed in the peripheral area PA of the substrate 110. For example, FIG. 2 illustrates first power supply wiring 125 through which low voltage power is applied to the light-emitting element PX and second power supply wiring 126 through which high voltage power is applied to the light-emitting element PX.

An organic film layer 116 may be disposed on the thin-film transistor TFT to act as a planarization film. The organic film layer 116 may include an organic material, or may include a composite of an organic insulator and an inorganic insulator. For example, the organic film layer may be formed of an organic material such as, for example, acrylic, benzocyclobutene (BCB), polyimide, or hexamethyldisiloxane (HMDSO).

The inorganic film layer 117 may be disposed over the organic film layer 116. For example, the organic film layer 116 may be disposed between the thin-film transistor TFT and the inorganic film layer 117.

In the display area DA, the light-emitting element PX electrically connected to the thin-film transistor TFT may be disposed on the inorganic film layer 117.

The light-emitting element PX may include a pixel electrode 130, a common electrode 150 positioned on the pixel electrode 130, and an emission layer 140 disposed between the pixel electrode 130 and the common electrode 150.

The pixel electrodes 130 may be disposed on the inorganic film layer 117. Each of the pixel electrodes 130 may be connected to the drain electrode 124 of the thin-film transistor TFT through via holes formed in the inorganic film layer 117 and the organic film layer 116.

The pixel electrode 130 may be conductive. The pixel electrode 130 may be formed of a metal alloy or a conductive compound. The pixel electrode 130 may be an anode.

The pixel electrode 130 may be a transmissive electrode, a semi-transmissive electrode, or a reflective electrode. In an example case in which the pixel electrode 130 is a transmissive electrode, the pixel electrode 130 may include a transparent metal oxide, for example, indium tin oxide (ITO), indium zinc oxide (IZO), zinc oxide (ZnO), indium tin zinc oxide (ITZO), or the like.

In an example case in which the pixel electrode 130 is a semi-transmissive electrode or a reflective electrode, the pixel electrode 130 may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg). In another example, the pixel electrode may have a structure of a plurality of layers including a reflective film or a semi-transmissive film formed of the above-described materials and a transparent conductive film formed of indium tin oxide (ITO), indium zinc oxide (IZO), zinc oxide (ZnO), indium tin zinc oxide (ITZO), or the like. For example, the pixel electrode 130 may have, but is not limited to, a three-layer structure of ITO/Ag/ITO.

The emission layer 140 may have a single layer structure formed of a single material, a single layer structure formed of a plurality of different materials, or a multiple layer structure including a plurality of layers formed of a plurality of different materials.

An interlayer (not illustrated) including the emission layer 140 may be provided over each pixel electrode 130.

The interlayer may include a low-molecular material or a high-molecular material. In an example case in which the interlayer includes a low molecular weight material, the interlayer may have a structure in which a hole injection layer, a hole transport layer, an electron transport layer, an electron injection layer, an electron injection layer, and the like are stacked in a single or composite structure. The interlayer may include various organic materials such as, for example, copper phthalocyanine, N,N-di(naphthalene-1-yl)-N,N'-diphenyl-benzidine (NPB), and tris-8-hydroxyquinoline aluminum (Alq3). The interlayer may be formed by various methods such as, for example, vacuum deposition.

In an example case in which the interlayer includes a polymeric material, a hole transport layer may generally be included. In this case, the hole transport layer may include PEDOT, and the emission layer may include a polymeric material such as, for example, polyphenylene vinylene (PPV) and polyfluorene. Such an interlayer may be formed by various methods, such as, for example, screen printing, inkjet printing, and laser induced thermal imaging (LITI).

The interlayer may be a layer formed integrally over the plurality of pixel electrodes 130. Alternatively, the interlayer may be a layer patterned to correspond to each of the plurality of pixel electrodes 130.

The common electrode 150 integrated with all light-emitting elements PX may be provided on the emission layer 140 of the light-emitting element PX.

The common electrode 150 may be a transmissive electrode, a semi-transmissive electrode, or a reflective electrode. In an example case in which the common electrode 150 is a transmissive electrode, the common electrode 150 may be formed of a transparent metal oxide, for example, indium tin oxide (ITO), indium zinc oxide (IZO), zinc oxide (ZnO), indium tin zinc oxide (ITZO), or the like.

The common electrode 150 may be formed as a transmissive electrode. In an example case in which the common electrode 150 is formed as a transmissive electrode, the common electrode 150 may include one or more materials selected from Ag, Al, Mg, Li, Ca, Cu, LiF/Ca, LiF/Al, MgAg, or CaAg, and may be provided in the form of a thin film having a thickness of several to tens of nm.

The light-emitting element PX may include a first light-emitting element, a second light-emitting element, and a third light-emitting element spaced apart from each other. In an example, the first light-emitting element may emit red light, the second light-emitting element may emit green light, and the third light-emitting element may emit blue light.

A pixel defining film 115 may be provided between the pixel electrodes 130 of each light-emitting element PX and the common electrode 150.

The pixel defining film 115 may have a first opening C1 surrounding the peripheral portions and exposing the central portion of each pixel electrode 130. For example, the pixel defining film 115 may include a first opening C1 covering the peripheral portions of each pixel electrode 130 and defining a light-emitting area LA of the light-emitting element PX.

The pixel defining film 115 may be formed of an organic material, for example, polyimide, hexamethyldisiloxane (HMDSO), or the like. In the present embodiment, the pixel defining film 115 is formed to include a light-blocking material surrounding the peripheral portions of each pixel electrode 130 and having a circular first opening C1. The light-blocking material may include, for example, at least one of carbon black, carbon nanotubes (CNTs), or a black dye.

The thin-film encapsulation layer 160 covering the display area DA is disposed on the common electrode 150. The thin-film encapsulation layer 160 seals the light-emitting element PX to inhibit degradation of the light-emitting element PX by moisture and oxygen contained in the ambient air. The thin-film encapsulation layer 160 may include a first inorganic layer 161, an organic layer 162, and a second inorganic layer 163, as illustrated in FIG. 2.

The first inorganic layer 161 may include silicon oxide, silicon nitride, silicon oxynitride, and/or the like. The first inorganic layer 161 may be uneven or include uneven portions.

The organic layer 162 covers the first inorganic layer 161, and the top surface of the organic layer 162 may be substantially flat. The organic layer 162 may include one or more materials selected from the group consisting of polyethylene terephthalate, polyethylene naphthalate, polycarbonate, polyimide, polyethylene sulfonate, polyoxymethylene, polyarylate, and polyacrylate hexamethyldisiloxane.

The second inorganic layer 163 covers the organic layer 162, and may include silicon oxide, silicon nitride, silicon oxynitride, and/or the like.

Because the thin-film encapsulation layer 160 is a multiple layer structure including the first inorganic layer 161, the organic layer 162, and the second inorganic layer 163 as described herein, in a case in which cracks occur in the thin-film encapsulation layer 160, the thin-film encapsulation layer 160 may prevent the cracks from being connected between the first inorganic layer 161 and the organic layer 162 or between the organic layer 162 and the second inorganic layer 163. As a result, the formation of a path for external moisture or oxygen to enter the display area DA may be prevented or reduced.

Although not illustrated in FIG. 2, a capping layer (not illustrated) may be provided between the common electrode 150 and the thin-film encapsulation layer 160 to improve light efficiency and protect the light-emitting element PX.

The touch sensing layer 170 may be provided on the thin-film encapsulation layer 160. The touch sensing layer 170 may include a first insulating layer 171, a second insulating layer 172 provided on the first insulating layer 171, and a plurality of touch electrodes 173 provided between the first insulating layer 171 and the second insulating layer 172. The touch electrodes 173 are not limited to the structure illustrated in FIG. 2, but may include a variety of electrode structures, such as, for example, a mesh electrode pattern and transparent segmented electrodes.

The touch sensing layer 170 may detect a touch input based on a change in mutual capacitance induced by the touch input. In an example in which a touch input is applied, the mutual capacitance is changed by the touch input, and the touch input may be detected by a touch sensor (not illustrated) connected to the touch sensing layer 170 which detects a changed position of the mutual capacitance. However, the present embodiment is not limited to a particular touch detection method.

Referring to FIG. 3, a pixel circuit PC may be connected to a display element, such as, for example, a light-emitting element PX. The pixel circuit PC may include a thin-film transistor TFT and a storage capacitor Cst. The thin-film transistor TFT may include, for example, a driving thin-film transistor T1 and a switching thin-film transistor T2. The light-emitting element PX may emit red, green, or blue light, or may emit red, green, blue, or white light.

The switching thin-film transistor T2 is connected to a scan line SL and a data line DL, and may transfer a data signal or a data voltage input from the data line DL to the driving thin-film transistor T1 based on a scanning signal or a switching voltage input from the scan line SL. The storage capacitor Cst is connected to the switching thin-film transistor T2 and a driving voltage line PL, and may store a voltage corresponding to the difference between the voltage transferred from the switching thin-film transistor T2 and a first power supply voltage ELVDD supplied to the driving voltage line PL.

The driving thin-film transistor T1 is connected to the driving voltage line PL and the storage capacitor Cst, and may control a driving current flowing from the driving voltage line PL to the light-emitting element PX in response to a voltage value stored in the storage capacitor Cst. The light-emitting element PX may emit light having a predetermined luminance by the driving current. The counter electrode of the light-emitting element PX may be supplied with a second supply voltage ELVSS.

FIG. 3 illustrates the pixel circuit PC including two thin-film transistors TFT and a single storage capacitor Cst, but the pixel circuit PC may include three, four, five, or more thin-film transistors TFT.

Referring again to FIG. 2, the antireflective layer 200 may be disposed on the display layer 100. In some embodiments, the antireflective layer 200 may be disposed on the light-emitting element PX, and the antireflective layer 200 may include the color filter 250 which filters light generated by the light-emitting element PX and the black matrix BM surrounding the color filter 250.

The color filter 250 may include a plurality of color filters, each of which may be disposed in a second opening C2 of the black matrix BM.

The color filter 250 may be disposed on the touch sensing layer 170 and may be disposed in the light-emitting area LA of each light-emitting element PX. For example, the color filter 250 may be disposed such that color filter 250 corresponds to the first opening C1 defining the light-emitting area LA of the light-emitting element PX. For example, a center of the color filter 250 may be aligned with a center of the first opening C1.

The color filter 250 may include a plurality of color filters which filter light generated by the light-emitting element PX and transmit the same to the outside. The color filter 250 may include a first color filter disposed on the first light-emitting element, a second color filter disposed on the second light-emitting element, and a third color filter disposed on the third light-emitting element.

The color filters may include a plurality of colors corresponding to the light-emitting areas LA of the respective light-emitting elements PX. For example, in an example case in which the first light-emitting element emits red light, the first color filter may filter red light, in an example case in which the second light-emitting element emits green light, the second color filter may filter green light, and in an example case in which the third light-emitting element emits blue light, the third color filter may filter blue light.

In this case, the first color filter, a red color filter, includes a red pigment or dye, the second color filter, a green color filter, includes a green pigment or dye, and the third color filter, a blue color filter, includes a blue pigment or dye. The red pigment, the green pigment, and the blue pigment may be any publicly known pigment conventionally used in the art to form color filters. For example, the red pigment may be a pigment of the C.I. pigment red series, the green pigment may be a pigment of the C.I. pigment green series, and the blue pigment may be a phthalocyanine-based pigment or indanthrone blue pigment.

Light emission efficiency may be improved by using the color filters 250 in the display device 10 instead of a polarizing layer. However, in the display device 10 using only the color filters 250, the respective color filters are matched to corresponding light-emitting elements and are uniformly arranged, which may result in a diffraction interference reflection pattern due to the periodic grating.

The antireflective layer 200 may include the black matrix BM as an optional embodiment. The black matrix BM may be disposed between the color filters on the touch sensing layer 170.

The black matrix BM is positioned on the pixel defining film 115 and defines an open area through which light passes. For example, the second opening C2 of the black matrix BM may correspond to the first opening C1. In an example, a center of the second opening C2 may be aligned with the center of the first opening C1.

The black matrix BM of the display area DA has the second opening C2 which opens the light-emitting area LA of each light-emitting element PX. The second opening C2 of the black matrix BM may be arranged to overlap the first opening C1 provided in the pixel defining film 115.

The black matrix BM of the peripheral area PA may surround the entire peripheral area PA without an opening. The black matrix BM surrounding the peripheral area PA may reduce the reflection of ambient light from various wiring arranged in the peripheral area PA.

The black matrix BM may include a material capable of blocking light. For example, the black matrix BM may include at least one of a metal such as, for example, chromium oxide (CrOx), an opaque organic film material, carbon black, carbon nanotubes, or a black dye. The black matrix BM may include a colorant such as, for example, a pigment or a dye. The black matrix BM may have a single or multiple layer structure.

In an embodiment, each or one of the display device 10 or an electronic device 1000 including the display device 10 may be implemented without a polarizer (i.e., be absent a polarizer). In some other approaches, a polarizer typically disposed over the color filter may allow external incident light, which is reflected from the top surface of the pixel electrode 130, a side surface of the first opening C1 of the pixel defining film 115, or the like, to pass only in a selected direction to prevent degradation of visibility and display quality, but light emitted from the emission layer 140 may be reduced. Therefore, the electronic device 1000 may be implemented without a polarizer, which may improve light emission efficiency and reduce power consumption for displaying a selected luminance.

In FIG. 2, the color filters are illustrated covering portions of the black matrix BM, but the black matrix BM may cover a portion of each of the color filters and the color filters may cover portions of the black matrix BM, depending on the order of formation of the black matrix BM and the color filters.

In another optional embodiment, in place of the black matrix BM, the antireflective layer 200 may be a combination of the first color filter, the second color filter, and the third color filter to have the same effect as the black matrix BM.

In FIGS. 1 and 2 above, the typical display device 10, in particular the organic light-emitting display device, has been described. However, in the typical display device 10, there is a problem that a reflection diffraction pattern occurs depending on the period of the light-emitting element PX. For a case in which a scattering layer is provided to solve this problem, a scattered rainbow phenomenon occurs, and for a case in which an elliptical/phase difference structure is applied, stains occur on the outer surface. The following will describe a lenticular structure applied to the light-emitting element PX overlapping the light-emitting area LA to solve the above problems.

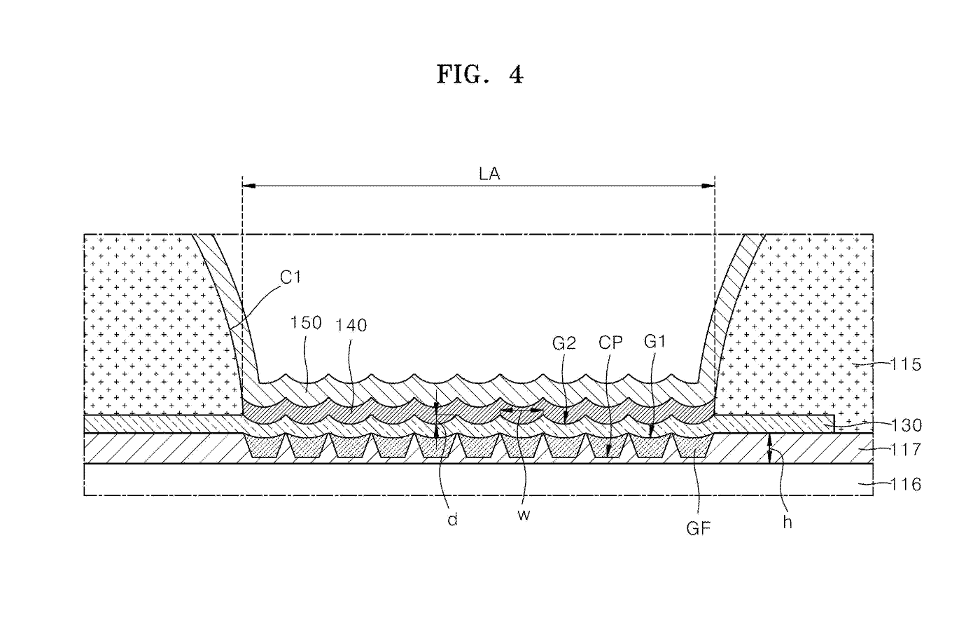

FIG. 4 is an enlarged view of area A of an example of the display device illustrated in FIG. 2.

Referring to FIG. 4, the display device 10 includes a substrate 110, a thin-film transistor TFT on the substrate 110, an inorganic film layer 117 on the thin-film transistor TFT, and a light-emitting element PX electrically connected to the thin-film transistor TFT and disposed on the inorganic film layer 117, in which the light-emitting element PX may include a pixel electrode 130, a common electrode 150 positioned on the pixel electrode 130, and an emission layer 140 disposed between the pixel electrode 130 and the common electrode 150.

In some embodiments, an organic film layer 116 may be further disposed between the thin-film transistor TFT and the inorganic film layer 117. A lenticular shape having a diameter of about 1 μm may be proposed to solve the scattering problem. However, because the organic film layer 116 includes an organic material, the characteristics of the organic film layer 116 may prevent patterning of a precise concave shape directly on the organic film layer 116, and even if dry etching is used after photoresist patterning on the organic film layer 116, resolution is lost and a skewing phenomenon occurs, thereby making it difficult to realize a lenticular shape having a diameter of 1 μmIn accordance with one or more embodiments of the present disclosure, by placing the inorganic film layer 117 on the organic film layer 116, concave portions CP having a lenticular shape with a diameter of 1 μm may be realized. In an example, embodiments of the present disclosure may include patterning concave portions CP directly on the inorganic film layer 117.

The inorganic film layer 117 including an inorganic material may be disposed over the organic film layer 116, and may include a plurality of fine concave portions CP. In an example, the inorganic film layer 117 may include silicates and/or silicides.

The concave portions CP may be disposed on the top surface of the inorganic film layer 117 overlapping the light-emitting area LA. A plurality of concave portions CP may be disposed on the top surface of the inorganic film layer 117. In an example, the concave portions CP may be randomly disposed on the top surface of the inorganic film layer 117, which may reduce and prevent reflection diffraction patterns. In some other embodiments, the concave portions CP may be disposed on the top surface of the inorganic film layer 117 according to a predetermined spacing, a predetermined pattern, or the like.

The concave portions CP may be in the form of blind holes which are open at the top of the inorganic film layer 117 and closed at the bottom of the inorganic film layer 117.

The concave portions CP of the inorganic film layer 117 may be formed by dry etching due to the nature of the inorganic material. In some cases, due to the nature of the inorganic material, the concave portions CP may be difficult to etch into a lenticular shape.

A filling material GF may be disposed in each of the plurality of concave portions CP and provide the inorganic film layer 117 with a finer lens shape. In some embodiments, the filling material GF is disposed in the blind holes of the concave portions CP, and the filling material GF may include an organic material.

The top surface of the filling material GF may have concave a first groove G1. For example, the first groove G1 may be recessed toward the bottom of the inorganic film layer 117 and form a lenticular shape.

The regions of the inorganic film layer 117 corresponding to the sides of the concave portions CP which define the concave portions CP may be thinner toward the top, i.e., have a pointed shape toward the top. As a result, the first groove G1 of the filling material GF may be realized in a finer lenticular shape, and a second groove G2 which is provided on the pixel electrode 130 and corresponds to the first groove G1 may also be realized in a finer lenticular shape.

The inorganic film layer 117 may be at least as thick as the minimum thickness at which the filling material GF may be disposed in the concave portions CP such that the first groove G1 may be formed. The thickness h of the inorganic film layer 117 may range from, for example, 0.8 to 1.8 μm. In another example, the thickness h of the inorganic film layer 117 may range from 0.8 to 1.5 μm.

The pixel electrode 130 is disposed on the top surface of the inorganic film layer 117, and the top surface of the pixel electrode 130 may include the second groove G2 being flush with the top surface of the filling material GF. In some aspects, a portion of a bottom surface of the pixel electrode 130 may correspond to the second groove G2 and be flush with the top surface of the filling material GF. For example, the second groove G2 corresponding to the first groove G1 provided on the top surface of the filling material GF may be formed on the top surface of the pixel electrode 130. A plurality of second grooves G2 may be provided on the top surface of the pixel electrode 130 and overlap the light-emitting area LA.

The second groove G2 may have a lenticular shape, which may reduce or prevent reflective diffraction patterns. In an example having this effect, the depth d of the second groove G2 may be 0.18 μm or less. Furthermore, the width w of the second groove G2 may range from 0.9 to 1.1 μm.

The emission layer 140 is disposed on the pixel electrode 130, and the top surface of the emission layer 140 may be flush with the top surface of the pixel electrode 130. For example, a concave lenticular shape may be provided on the top surface of the emission layer 140 and correspond to the second groove G2 disposed on the top surface of the pixel electrode 130. This concave lenticular shape may be provided on the top surface of the emission layer 140 overlapping the light-emitting area LA.

The common electrode 150 may be integrally provided on the emission layer 140 and the pixel defining film 115, and the top surface of the common electrode 150 may be flush with the top surface of the emission layer 140. For example, the top surface of the common electrode 150 may be provided such that the top surface of the common electrode 150 corresponds to the concave lenticular shape provided on the top surface of the emission layer 140.

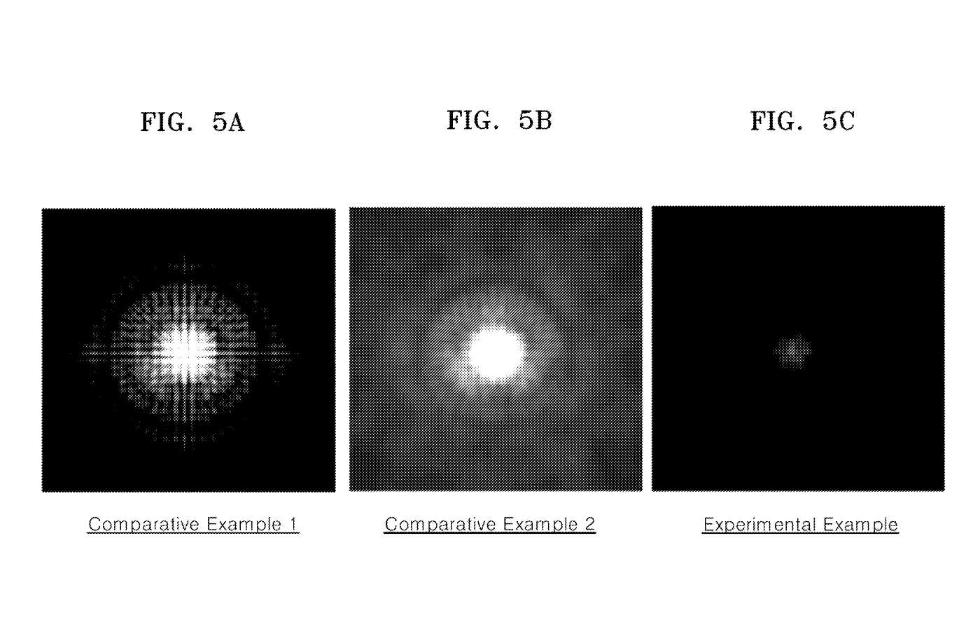

By including the filling material GF disposed in the concave portions CP of the inorganic film layer 117 with the first groove G1 provided on the top surface and the pixel electrode 130 disposed on the filling material GF with the second groove G2 provided on the top surface to mate with the first groove G1, the display device 10 may reduce or prevent reflective diffraction patterns, stains on the outer surface, and scattered rainbows, which will be described in detail with reference to FIGS. 5A through 5C.

FIGS. 5A, 5B, and 5C illustrate images of reflection diffraction patterns of display devices according to comparative examples and an experimental example.

FIG. 5A is an image of a reflection diffraction pattern of a display device of Comparative Example 1, FIG. 5B is an image of a reflection diffraction pattern of a display device of Comparative Example 2, and FIG. 5C is an image of a reflection diffraction pattern of a display device 10 according to an embodiment of the disclosure.

The display device of Comparative Example 1 may include a substrate, a thin-film transistor on the substrate, a light-emitting element electrically connected to the thin-film transistor, and a color filter on the light-emitting element. The display device of Comparative Example 1 may not have a scattering layer disposed between the color filter and the light-emitting element, and may not have a concave groove formed in the top surface of the pixel electrode of the light-emitting element.

Referring to FIG. 5A, a reflected diffraction pattern, i.e., visual distortions and stains caused by the reflection and diffraction of light, is clearly visible on the screen of the display device of Comparative Example 1 having the above configuration.

Due to the reflective diffraction pattern, a user of the display device of Example 1 may notice undesirable visual distortion or scattering when viewing the screen of the display device of Example 1. For example, the display device of Example 1 may suffer from distortion of images on the screen, changes in clarity and color, and glare.

To reduce the problems of the display device of Example 1, the display device of Example 2 may include a substrate, a thin-film transistor on the substrate, a light-emitting element electrically connected to the thin-film transistor, a color filter on the light-emitting element, and a scattering layer between the color filter and the light-emitting element. However, the display device of Comparative Example 2 may not have a concave groove provided on the top surface of the pixel electrode of the light-emitting element.

Referring to FIG. 5B, reflection diffraction patterns on the screen of the display device of Example 2 having the above configuration may be less visible than those on the display device of Example 1, and in this respect, the display quality may be improved.

However, in the display device of Example 2, a scattered rainbow phenomenon, i.e., a phenomenon in which light is scattered in a plurality of directions due to a scattering layer and colors are separated to appear like a rainbow, may be seen.

The visibility of the reflected diffraction pattern in the display device of Example 2 is reduced as compared to the display device of Example 1 because a scattering layer is further disposed, but a scattered rainbow phenomenon may reduce clarity and color accuracy, which may still result in the problem of degraded display quality.

A display device 10 according to the experimental example of the disclosure for improving display quality over the display device of Comparative Example 1 and the display device of Comparative Example 2 may include a substrate 110, a thin-film transistor TFT on the substrate 110, an inorganic film layer 117 including a plurality of concave portions CP on the thin-film transistor TFT, a light-emitting element PX being flush with the concave portions CP on the inorganic film layer 117, and a color filter 250 on the light-emitting element PX.

Referring to FIG. 5C, a less clear reflection diffraction pattern is visible on the screen of the display device 10 of the experimental example having the above configuration as compared to the display device of the comparative example 1 and the display device of the comparative example 2.

Furthermore, because the display device 10 of the experimental example does not include a scattering layer, the scattered rainbow phenomenon occurring in the display device of the comparative example 2 is not visible.

Because the display device 10 of the disclosure includes the inorganic film layer 117 including a plurality of concave portions CP and the top surface of the pixel electrode 130 being flush with the top surface of the filling material GF disposed in the concave portions CP, the display quality may be further improved.

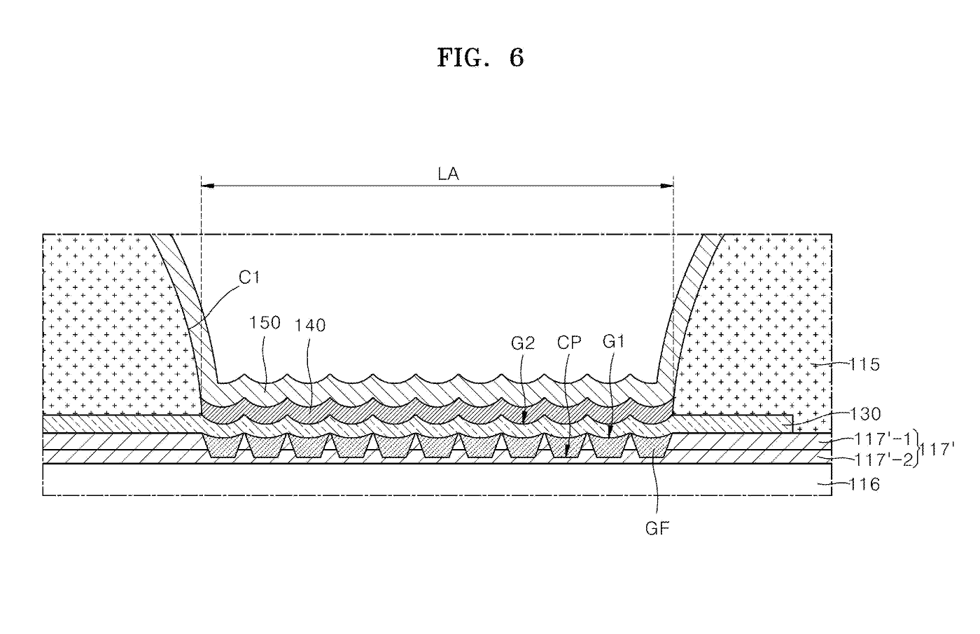

FIG. 6 is an enlarged view of area A of another example of the display device illustrated in FIG. 2.

Referring to FIG. 6, the display device 10 may include an inorganic film layer 117’ including a plurality of layers.

The inorganic film layer 117’ may include a first inorganic film layer 117’-1 and a second inorganic film layer 117’-2. The first inorganic film layer 117’-1 may include a silicate, and the second inorganic film layer 117’-2 may include a silicide. In another example, the first inorganic film layer 117’-1 may include a silicide, and the second inorganic film layer 117’-2 may include a silicate.

In another example, or differently from that illustrated in FIG. 6, the inorganic film layer of the display device 10 may be a layer in which the first inorganic film layer 117’-1 and the second inorganic film layer 117’-2 are alternately stacked. For example, the inorganic film layer of the display device 10 may be a layer in which the first inorganic film layer 117’-1 and the second inorganic film layer 117’-2 are alternately stacked at least one time.

The features of the inorganic film layer 117 described with reference to FIG. 4 may be applied to the display device 10 of FIG. 6 in the same manner, except for inconsistency with the above description of the inorganic film layer 117’. Furthermore, the display device 10 of FIG. 6 may include the other configurations of the display device 10 described in FIGS. 3 and 4 in the same manner.

In the following, a process for fabricating the display device 10 of the disclosure will be described in detail.

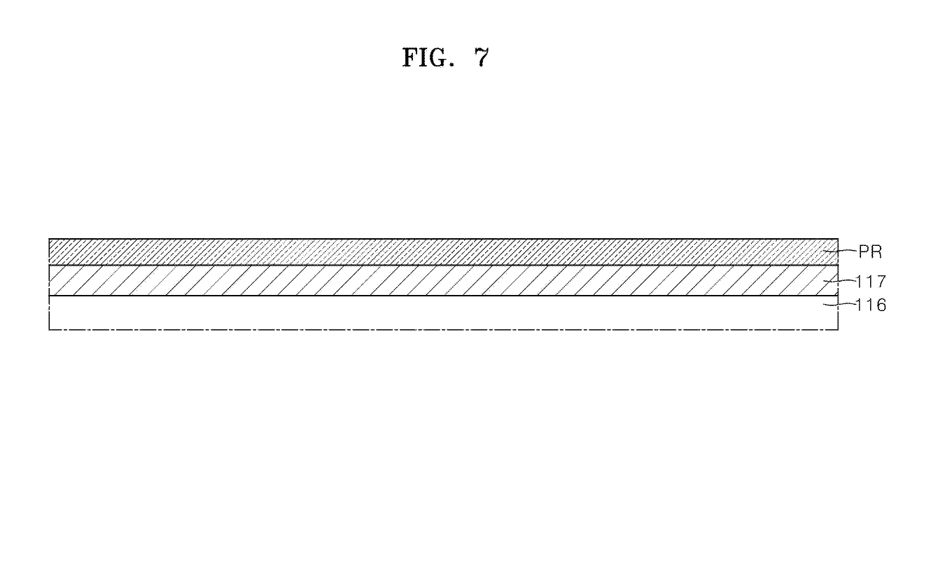

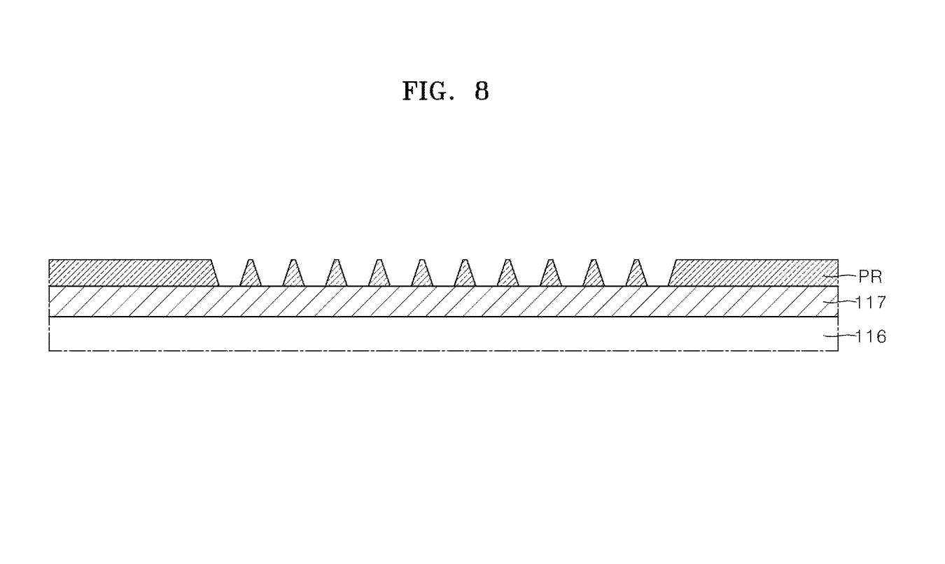

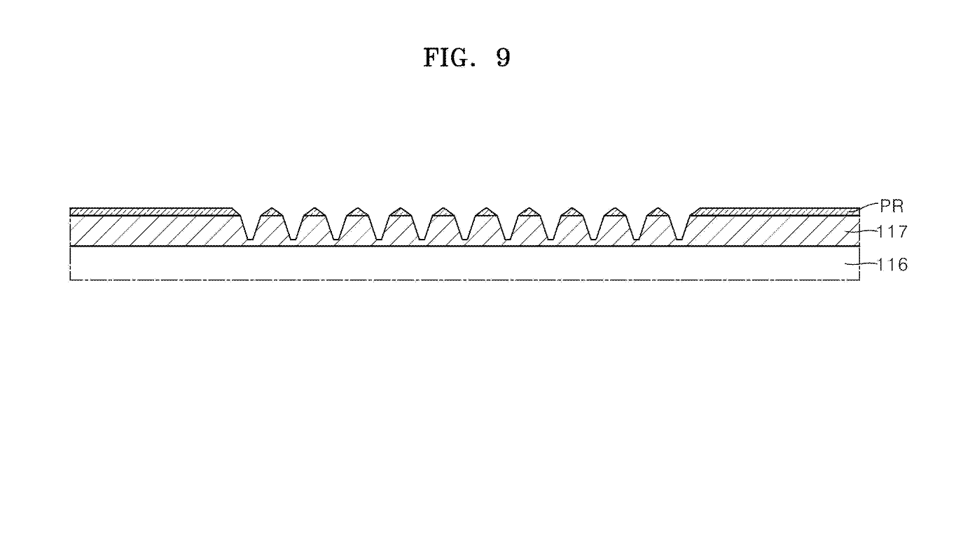

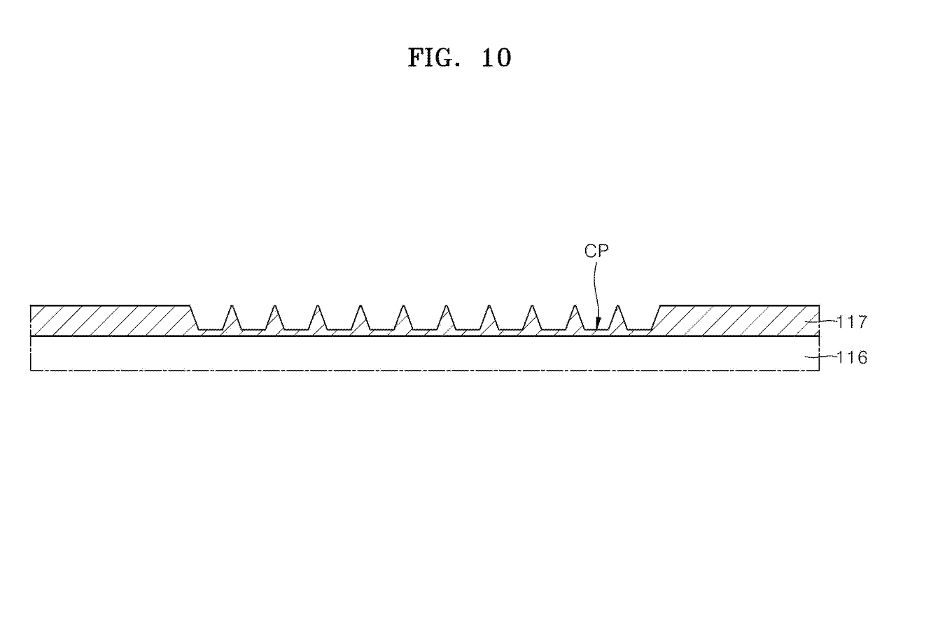

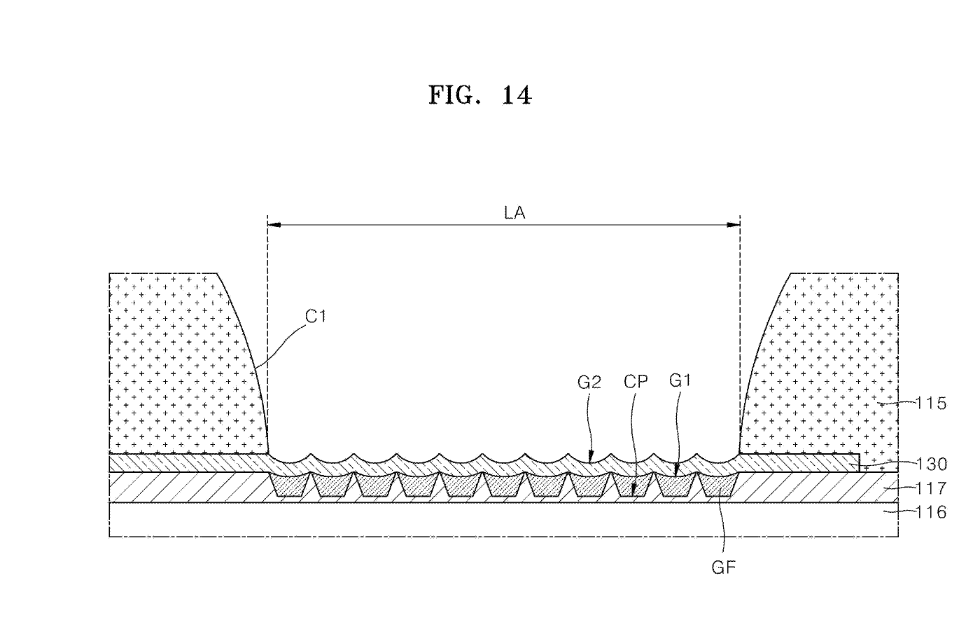

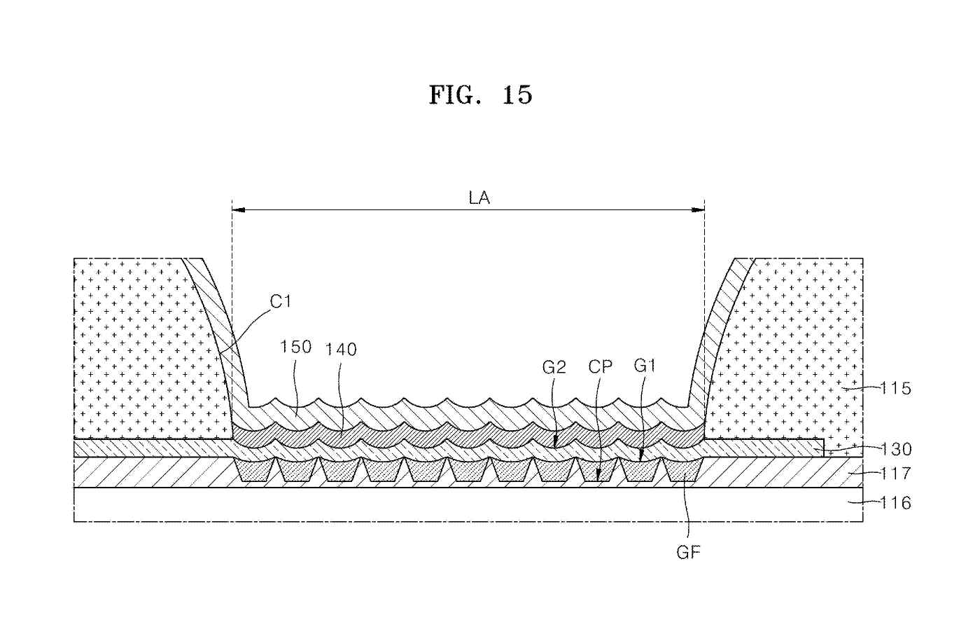

FIGS. 7 to 15 are cross-sectional views illustrating a fabrication process of a display device according to embodiments of the disclosure.

In the descriptions of the method and processes herein, the operations may be performed in a different order than the order shown and/or described, or the operations may be performed in different orders or at different times. Certain operations may also be left out, one or more operations may be repeated, or other operations may be added. Descriptions that an element “may be disposed,” “may be formed,” “may be provided,” and the like include methods, processes, and techniques for disposing, forming, providing, and modifying the element, and the like in accordance with example aspects described herein.

A method of fabricating the display device 10 of the disclosure may include the operations of: preparing a substrate 110 and a thin-film transistor TFT on the substrate 110; forming an inorganic film layer 117 including a plurality of concave portions CP on the thin-film transistor TFT; forming a filling material GF in each of the plurality of concave portions CP; and forming a light-emitting element PX which is electrically connected to the thin-film transistor TFT and disposed on the inorganic film layer 117.

Referring to FIGS. 7 to 10, the operation of forming the inorganic film layer 117 may include forming a photoresist layer PR by coating the inorganic film layer 117 with a photoresist material, forming a photoresist pattern on the photoresist layer PR, and patterning the concave portions CP using the photoresist pattern as a mask.

In some embodiments, the method may include forming a photoresist pattern by performing an exposure process and a development process on the inorganic film layer 117 on the photoresist layer PR coated with a photoresist material, i.e., on a region of the inorganic film layer 117 where concave portions CP are to be formed, using a mask.

After the operation of forming the photoresist pattern, the method may include patterning the inorganic film layer 117 using the photoresist pattern as a mask, i.e., performing an etching process on the photoresist pattern.

The method may include adjusting the depth and the width of the concave portions CP by adjusting the light intensity in the exposure process and by adjusting the patterning and etching processes.

After the operation of patterning the inorganic film layer 117, the method may include performing a stripping operation of removing the remaining photoresist pattern. The stripping operation may form concave portions CP on the surface of the inorganic film layer 117.

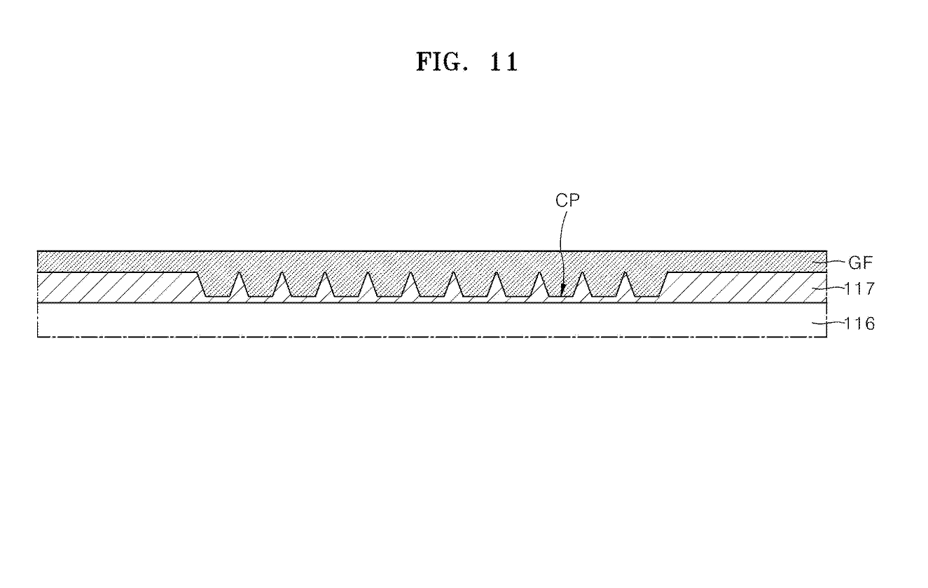

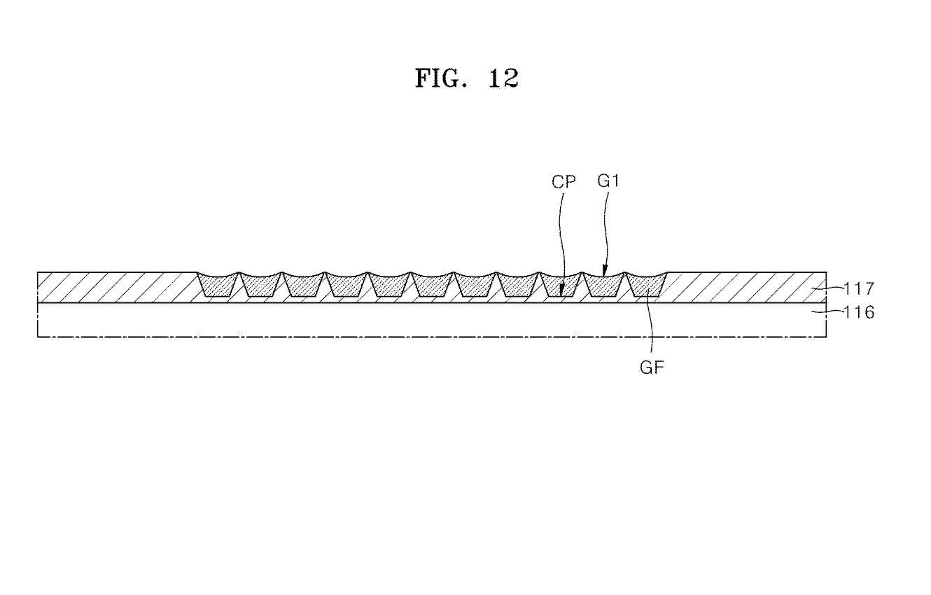

Referring to FIGS. 11 and 12, the operation of forming the inorganic film layer 117 may be followed by the operation of forming a filling material GF on the concave portions CP. The operation of forming the filling material GF in the concave portions CP may be performed between the operation of forming the inorganic film layer 117 and the operation of forming the light-emitting element PX.

After the operation of forming the inorganic film layer 117, the method may include coating the inorganic film layer 117 with the material substance of the filling material GF. Thereafter, embodiments of the present disclosure may include evaporating the solvent from the material substance of the filling material GF, performing a baking process, followed by performing a development process, and then performing a baking process again to form the filling material GF in the concave portions CP.

The top surface of the filling material GF produced by the above-described process may include concave first grooves G1.

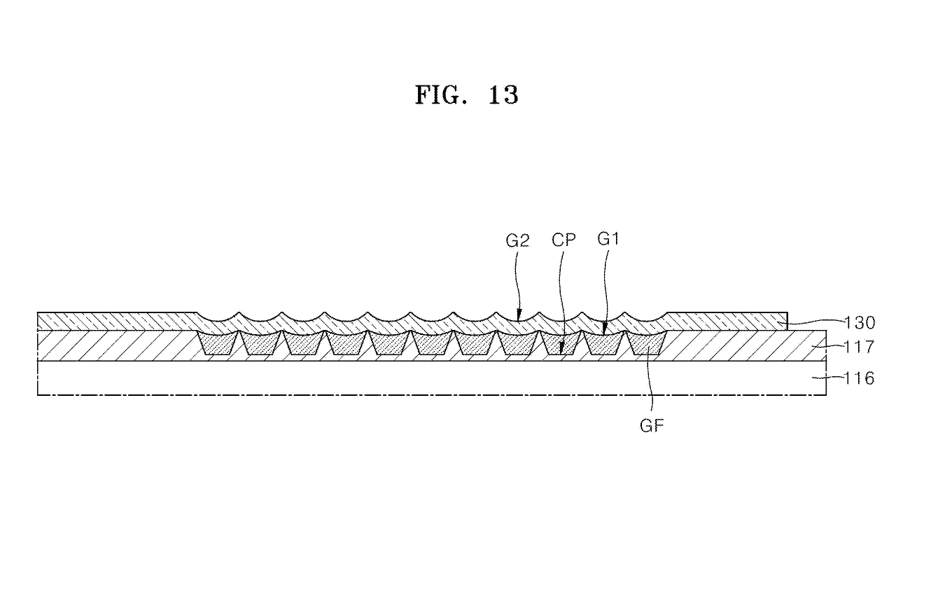

Referring to FIGS. 13 to 15, the operation of forming the light-emitting element PX may include an operation of placing a pixel electrode 130 on the inorganic film layer 117 and the filling material GF, an operation of placing an emission layer 140 on the pixel electrode 130, and an operation of placing a common electrode 150 on the emission layer 140. Descriptions herein of placing an element (e.g., pixel electrode 130, emission layer 140, common electrode 150, and the like) on another element may include forming the element on the other element.

By placing the pixel electrode 130 on the inorganic film layer 117 and the filling material GF, a second groove G2 being flush with the top surface of the pixel electrode 130 may be formed over the top surface of the filling material GF. In an example, the second groove G2 may be formed such that the depth d of the second groove G2 is 0.18 μm or less. Furthermore, the second groove G2 may be formed such that the width w of the second groove G2 ranges from 0.9 to 1.1 μm. The second groove G2 may be provided on the top surface of the pixel electrode 130 overlapping the light-emitting area LA.

Between the operation of placing the pixel electrode 130 and the operation of placing the emission layer 140, the method may further include performing an operation of forming a pixel defining film 115 covering the peripheral portions of the pixel electrode 130 and having a first opening C1 defining a light-emitting area LA of the light-emitting element PX.

After the operation of forming the pixel defining film 115, the method may include providing the emission layer 140 on the pixel electrode 130. In some embodiments, the emission layer 140 may be formed on the pixel electrode 130 and overlap the light-emitting area LA. The top surface of the emission layer 140 may be flush with the top surface of the pixel electrode 130. For example, the emission layer 140 may be formed such that the top surface of the emission layer 140 has a lenticular shape corresponding to the second groove G2.

After the operation of forming the emission layer 140, the method may include providing a common electrode 150 on the emission layer 140 and the pixel defining film 115. The top surface of the common electrode 150 overlapping the light-emitting area LA may be flush with the top surface of the emission layer 140. For example, the common electrode 150 may be formed such that the bottom surface of the common electrode 150 in the region overlapping the light-emitting area LA has a lenticular shape corresponding to the top surface of the emission layer 140 having a lenticular shape.

The display device 10 of the disclosure may be fabricated according to the above-described processes, and the display device 10 having a concave lenticular shape formed in the light-emitting element PX of the light-emitting area LA may have improved display quality.

The display device 10 according to embodiments may be used in a variety of electronic devices 1000. The electronic device 1000 according to embodiments includes the above-described display device 10, and may further include modules or devices having other additional functions in addition to the display device 10.

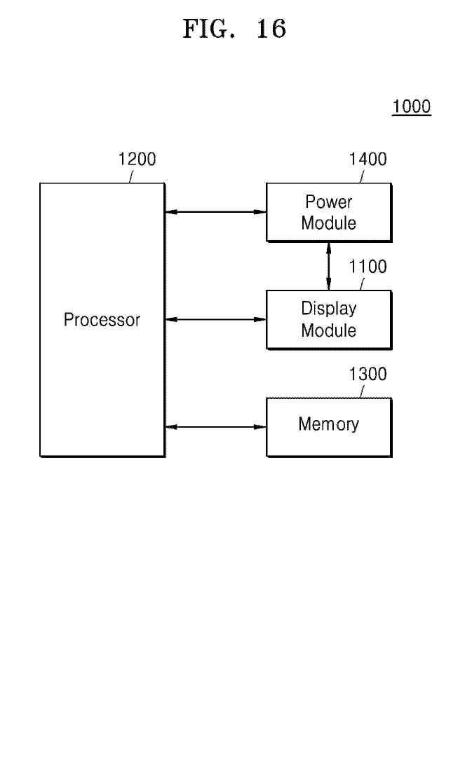

FIG. 16 is a block diagram illustrating an electronic device according to embodiments of the disclosure. Referring to FIG. 16, the electronic device 1000 according to embodiments may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), or a controller.

The memory 1300 may store data information for operation of the processor 1200 or the display module 1100. In an example case in which the processor 1200 executes an application stored in the memory 1300, image data signals and/or input control signals may be transferred to the display module 1100, and the display module 1100 may process the received signals to output image information on a display screen.

The power module 1400 may include a power supply module, such as, for example, a power adapter or a battery device, and a power conversion module which converts power supplied by the power supply module to generate power for operation of the electronic device 1000.

At least one of each of the above-described configurations of the electronic device 1000 may be included in the display device 10 according to the foregoing embodiments. Furthermore, some of individual modules functionally included in a single module may be included in the display device and others of the individual modules may be provided separately from the display device. For example, the display device 10 may include the display module 1100, and the processor 1200, the memory 1300, and the power module 1400 may be provided as other devices in the electronic device 1000 other than display device 10.

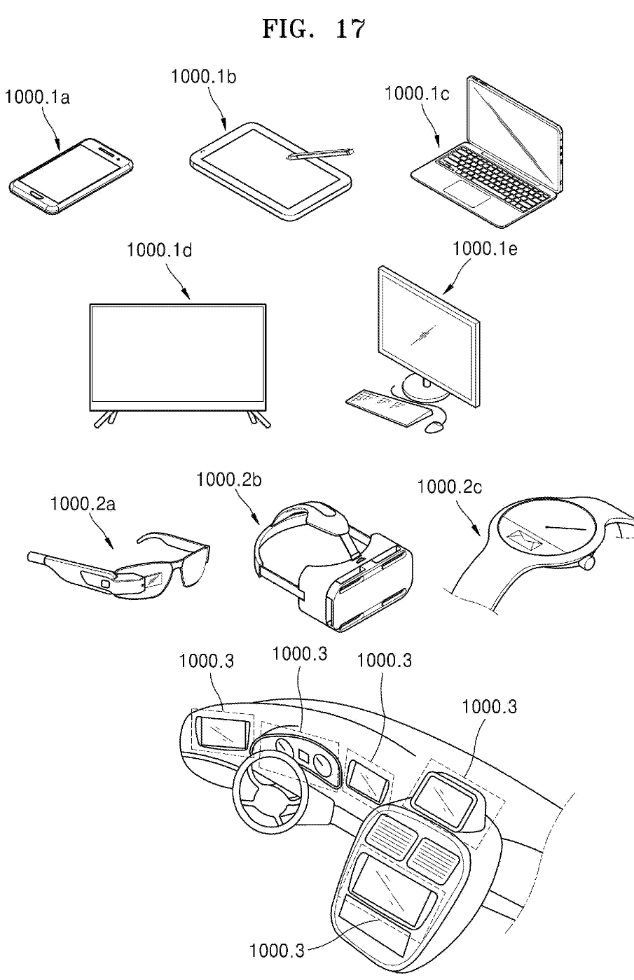

FIG. 17 schematically illustrates electronic devices according to various embodiments.

Referring to FIG. 17, various electronic devices in which the display device 10 according to embodiments is used include not only electronic devices for displaying images, such as, for example, a smartphone 1000.1a, a tablet 1000.1b, a laptop 1000.1c, a television 1000.1d, a desk monitor 1000.1e, but also wearable electronic devices including a display device, such as, for example, smart glasses 1000.2a, a head mounted display 1000.2b, and a smart watch 1000.2c, and automotive electronic devices 1000.3 including a display device, such as, for example, an instrument panel, a center fascia, a center information display (CID), and a room mirror display, disposed on the dashboard of a vehicle.

According to embodiments of the disclosure, provided are a display device in which concave shapes are arranged in light-emitting areas of light-emitting elements to improve display quality, a method of fabricating the display device, and an electronic device.

However, the effects of the disclosure are not limited to those described herein, and other technical effects not mentioned will be apparent to a person of ordinary knowledge in the art from the following description of the disclosure.

The respective embodiments described herein are embodiments that may be practiced independently, but the respective structures of the embodiments may be used in combination with other embodiments.

The disclosure has been described as above with reference to the embodiments illustrated in the drawings, which are illustrative examples, and a person of ordinary knowledge in the art will appreciate that various modifications and variations of the embodiments are possible. Accordingly, the true scope and spirit of the disclosure shall be defined by the appended claims.

The particular implementations illustrated and described in the embodiments are examples and are not intended to limit the scope of the embodiments in any manner. Furthermore, a component may not be essential to the practice of the disclosure unless the element is specifically described as “essential” or “critical”.

The use of the term “the” and similar reference terms in the context of describing the embodiments (particularly in the claims) are to be construed to cover both the singular and the plural. Furthermore, the specification of a range herein includes inventions in which individual values within the range are applied (unless otherwise indicated), as if each individual value within the range were specified in the detailed description. Finally, the operations of the method according to the disclosure may be performed in any appropriate order, unless the order of the operations is explicitly stated or otherwise. The disclosure is not necessarily limited to the order in which the operations are described. The use of any examples or illustrative terms herein is for the purpose of describing the embodiments in detail and the scope of the embodiments is not limited to the examples or illustrative terms unless defined by the claims. Furthermore, a person of ordinary knowledge in the art will appreciate that various modifications, combinations, and alterations are possible depending on the design conditions and factors within the scope of the appended claims or equivalents thereof.

What is claimed is:

1. A display device comprising:
a substrate;
a thin-film transistor on the substrate;
an inorganic film layer on the thin-film transistor; and
a light-emitting element electrically connected to the thin-film transistor and disposed on the inorganic film layer,
wherein:
the light-emitting element comprises a pixel electrode, a common electrode positioned on the pixel electrode, and an emission layer disposed between the pixel electrode and the common electrode,
the inorganic film layer comprises a plurality of concave portions,
a filling material is disposed in each of the plurality of concave portions,
a top surface of the filling material comprises a concave first groove, and
a top surface of the pixel electrode comprises a second groove being flush with the top surface of the filling material.

2. The display device of claim 1, wherein:
a top surface of the emission layer is flush with the top surface of the pixel electrode, and
a top surface of the common electrode is flush with the top surface of the emission layer.

3. The display device of claim 1, wherein a depth of the second groove is 0.18 μm or less.

4. The display device of claim 1, wherein a width of the second groove ranges from 0.9 μm to 1.1 μm.

5. The display device of claim 1, wherein a thickness of the inorganic film layer ranges from 0.8 μm to 1.8 μm.

6. The display device of claim 1, further comprising an organic film layer between the thin-film transistor and the inorganic film layer.

7. The display device of claim 1, wherein the filling material comprises an organic material.

8. The display device of claim 1, further comprising a pixel defining film covering peripheral portions of the pixel electrode and having a first opening defining a light-emitting area of the light-emitting element.

9. The display device of claim 8, wherein:
the second groove is provided as a plurality of second grooves; and
the plurality of second grooves are provided on the top surface of the pixel electrode and overlap the light-emitting area.

10. The display device of claim 8, further comprising a color filter which is disposed corresponding to the first opening.

11. The display device of claim 8, further comprising a black matrix positioned on the pixel defining film and having a second opening corresponding to the first opening.

12. A method of fabricating a display device, the method comprising:
preparing a substrate and a thin-film transistor on the substrate;
forming an inorganic film layer comprising a plurality of concave portions on the thin-film transistor;
forming a filling material in each of the plurality of concave portions; and
forming a light-emitting element which is electrically connected to the thin-film transistor and disposed on the inorganic film layer,
wherein:
the light-emitting element comprises a pixel electrode, a common electrode positioned on the pixel electrode, and an emission layer disposed between the pixel electrode and the common electrode,
a top surface of the filling material comprises a concave first groove, and
a top surface of the pixel electrode comprises a second groove being flush with the top surface of the filling material.

13. The method of claim 12, wherein the forming of the inorganic film layer comprises:
forming a photoresist layer by coating the inorganic film layer with a photoresist material;
forming a photoresist pattern on the photoresist layer; and
patterning the concave portions using the photoresist pattern as a mask.

14. The method of claim 12, wherein forming the filling material in each of the concave portions is between the forming of the inorganic film layer and the forming of the light-emitting element.

15. The method of claim 12, wherein the forming of the light-emitting element comprises:
placing the pixel electrode on the inorganic film layer and the filling material;
placing the emission layer on the pixel electrode;
forming a pixel defining film covering peripheral portions of the pixel electrode and having a first opening defining a light-emitting area of the light-emitting element; and
placing the common electrode on the emission layer,
wherein the second groove is provided as a plurality of second grooves provided on the top surface of the pixel electrode and overlapping the light-emitting area.

16. The method of claim 12, wherein:
a top surface of the emission layer is flush with the top surface of the pixel electrode, and
a top surface of the common electrode is flush with the top surface of the emission layer.

17. The method of claim 12, wherein a width of the second groove ranges from 0.9 μm to 1.1 μm.

18. An electronic device comprising a display device, wherein the display device comprises:
a substrate;
a thin-film transistor on the substrate;
an inorganic film layer on the thin-film transistor; and
a light-emitting element electrically connected to the thin-film transistor and disposed on the inorganic film layer,
wherein:
the light-emitting element comprises a pixel electrode, a common electrode positioned on the pixel electrode, and an emission layer disposed between the pixel electrode and the common electrode,
the inorganic film layer comprises a plurality of concave portions,
a filling material is disposed in each of the plurality of concave portions,
a top surface of the filling material comprises a concave first groove, and
a top surface of the pixel electrode comprises a second groove being flush with the top surface of the filling material.

19. The electronic device of claim 18, further comprising an antireflective layer disposed on the light-emitting element,
wherein the antireflective layer comprises:
a color filter which filters light generated by the light-emitting element; and
a black matrix surrounding the color filter.

20. The electronic device of claim 19, wherein the electronic device is absent a polarizer.
